(19) United States
(12) Patent Application Publication
(10) Pub. No.: US 2026/0173362 A1
(43) Pub. Date: Jun. 18, 2026

(54) SEMICONDUCTOR STRUCTURE AND METHOD FOR FORMING THE SAME

(71) Applicant: Winbond Electronics Corp., Taichung City (TW)

(72) Inventors: Yu-Po WANG, Kaohsiung City (TW); Wei-Che CHANG, Taichung City (TW); Te-Hsuan PENG, Hsinchu County (TW)

(21) Appl. No.: 19/073,598

(22) Filed: Mar. 7, 2025

(30) Foreign Application Priority Data
Dec. 17, 2024 (TW) 113149038

(51) Int. Cl. H10B 12/00

(52) U.S. Cl. CPC H10B 12/50; H10B 12/09

(57) ABSTRACT

A semiconductor structure is provided. The semiconductor structure includes a substrate and landing pads. The substrate has an array area and a peripheral area, and the landing pads are disposed on the substrate and in the array area. The semiconductor structure also includes conductive pillars disposed on the landing pads and a bottom support layer disposed between the bottoms of the conductive pillars. The semiconductor structure further includes a protective layer disposed on the bottom support layer and an additional support layer disposed on the protective layer. Moreover, the semiconductor structure includes a central support layer disposed above the additional support layer and a top support layer disposed above the central support layer. The additional support layer, the central support layer, and the top support layer are all disposed between the conductive pillars.

### CROSS REFERENCE TO RELATED APPLICATIONS

This application claims priority of Taiwan Patent Application No. 113149038, filed on Dec. 17, 2024, the entirety of which is incorporated by reference herein.

### BACKGROUND OF THE INVENTION

### Field of the Invention

The present disclosure relates to a semiconductor structure and a method for forming the same, and in particular it relates to a semiconductor structure that includes a protective layer and an additional support layer, and a method for forming the same.

### Description of the Related Art

The continuous advancements being made in the miniaturization and densification of integrated circuits has led to a reduction in the size of components such as transistors and capacitors. However, the process of fabricating conductive pillars with a high aspect ratio in miniaturized and densely packed semiconductor structures can easily result in tilting, which can cause adjacent conductive pillars to connect and form a short circuit. Alternatively, due to the instability in fabricating conductive pillars, the conductive pillars may fail to connect with the landing pads of the transistors, resulting in an open circuit. Both of these issues can reduce the yield of memory devices and adversely affect their overall performance.

### BRIEF SUMMARY OF THE INVENTION

The semiconductor structure according to the embodiments of the present disclosure includes a protective layer and an additional support layer, which may provide enhanced mechanical strength, thereby improving the tilting of conductive pillars and effectively reducing the possibility of short circuits caused by adjacent conductive pillars connecting. Furthermore, the protective layer and the additional support layer may improve the stability of the semiconductor structure during the manufacturing process, thereby reducing the probability of open circuits.

The present disclosure provides a semiconductor structure that includes a substrate and multiple landing pads. The substrate includes an array area and a peripheral area, and the landing pads are disposed on the substrate and in the array area. The semiconductor structure also includes multiple conductive pillars and a bottom support layer. The conductive pillars are disposed on the landing pads, and the bottom support layer is disposed between the bottoms of the conductive pillars. The semiconductor structure further includes a protective layer and an additional support layer. The protective layer is disposed on the bottom support layer, and the additional support layer is disposed on the protective layer. Moreover, the semiconductor structure includes a central support layer and a top support layer. The central support layer is disposed above the additional support layer, and the top support layer is disposed above the central support layer. The additional support layer, the central support layer, and the top support layer are all between the conductive pillars.

The present disclosure also provides a method for forming a semiconductor structure, which includes the following steps. A substrate is provided, wherein the substrate has an array area and a peripheral area. Multiple landing pads are formed on the substrate, wherein the landing pads are in the array area. A bottom support layer, a protective layer, an additional support layer, a first sacrificial layer, a central support layer, a second sacrificial layer, and a top support layer are sequentially formed above the substrate. Multiple first vias are formed in the array area, wherein the first vias penetrate the top support layer, the second sacrificial layer, the central support layer, the first sacrificial layer, the additional support layer, the protective layer, and the bottom support layer, and expose the landing pads. A conductive layer is formed on the bottoms and sidewalls of the first vias to form multiple conductive pillars. Second vias that are interleaved with the first vias are formed in the array area, wherein each second via at least partially overlaps adjacent first vias. The second sacrificial layer and the first sacrificial layer are removed through the second vias, and portions of the top support layer, the central support layer, and the additional support layer that correspond to the second vias are removed, so that the remaining additional support layer, central support layer, and top support layer are all between the conductive pillars.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 to FIG. 4 and FIG. 6 to FIG. 11 are partial cross-sectional views illustrating a method for forming a semiconductor structure at various stages according to an embodiment of the present disclosure.

FIG. 5 is a partial top view illustrating the vias and the conductive pillars according to an embodiment of the present disclosure.

FIG. 12 is a partially enlarged cross-sectional view illustrating region E of the semiconductor structure according to an embodiment of the present disclosure.

FIG. 13 is a partial cross-sectional view illustrating the semiconductor structure when defects occur according to some other embodiments of the present disclosure.

### DETAILED DESCRIPTION OF THE INVENTION

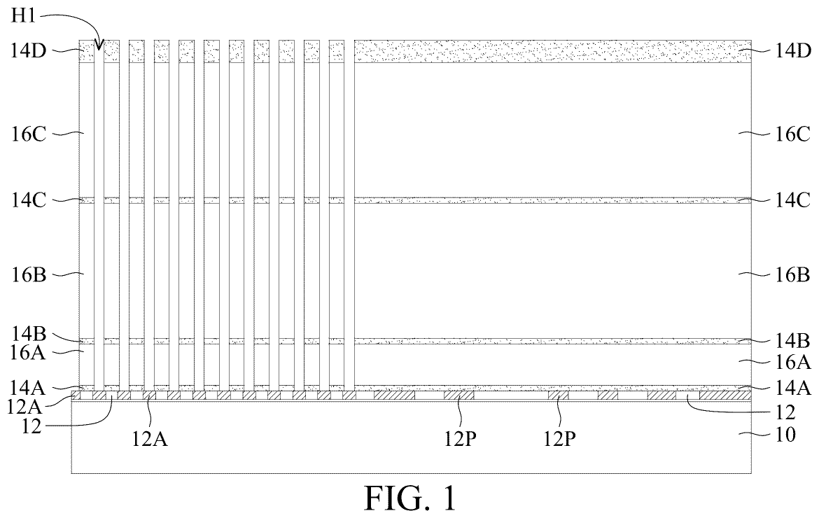

FIG. 1 to FIG. 4 and FIG. 6 to FIG. 11 are partial cross-sectional views illustrating a method for forming a semiconductor structure 100 at various stages according to an embodiment of the present disclosure. It should be noted that some components of the semiconductor structure 100 have been omitted in FIG. 1 to FIG. 4 and FIG. 6 to FIG. 11 for the sake of brevity.

Referring to FIG. 1, a substrate 10 that has an array area 10A and a peripheral area 10P is provided. For example, the peripheral area 10P may be adjacent to the array area 10A, or the peripheral area 10P may surround the array area 10A.

The substrate 10 may be part of a transistor (e.g., a metal-oxide-semiconductor field-effect transistor (MOSFET)). For example, the substrate 10 may include various components (not shown), such as active devices, passive devices, interconnection structures, or a combination thereof. Active devices may include, for example, transistors or diodes. Passive devices may include, for example, capacitors, inductors, or resistors. The interconnection structure may include multiple layers of metal wiring and vias formed in a dielectric structure. The multiple layers of metal wiring and vias are electrically connected to the various components to form functional circuits.

Next, multiple landing pads 12A are formed on the substrate 10, and the landing pads 12A are in the array area 10A. Moreover, during the formation of the landing pads 12A, multiple metal pads 12P are also formed on the substrate 10, and the metal pads 12P are in the peripheral area 10P. In more detail, in one embodiment, an insulating layer 12 is formed on the substrate 10, and the insulating layer 12 is disposed between the landing pads 12A and between the metal pads 12P (and between the landing pads 12A and the metal pads 12P). For example, the insulating layer 12 may be formed using processes such as chemical vapor deposition (CVD), atomic layer deposition (ALD), molecular beam epitaxy (MBE), liquid-phase epitaxy, any similar process, or a combination thereof, but the present disclosure is not limited thereto.

The landing pads 12A and the metal pads 12P may include gold, nickel, platinum, palladium, iridium, titanium, chromium, tungsten, aluminum, copper, an alloy thereof, or a combination thereof. The landing pads 12A and the metal pads 12P may be formed using physical vapor deposition (PVD), chemical vapor deposition (CVD), atomic layer deposition (ALD), evaporation, sputtering, or a combination thereof, but the present disclosure is not limited thereto.

Next, a bottom support layer 14A, a protective layer 16A, an additional support layer 14B, a sacrificial layer 16B, a central support layer 14C, a sacrificial layer 16C, and a top support layer 14D are sequentially formed above the substrate 10, and more specifically on the insulating layer 12. In one embodiment, the material of the protective layer 16A is different from the material of the additional support layer 14B. In one embodiment, the protective layer 16A and the additional support layer 14B exhibit high etching selectivity.

In one embodiment, the bottom support layer 14A, the additional support layer 14B, the central support layer 14C, and the top support layer 14D include nitrides. Moreover, in one embodiment, the protective layer 16A, the sacrificial layer 16B, and the sacrificial layer 16C include oxides. For example, the bottom support layer 14A, the protective layer 16A, the additional support layer 14B, the sacrificial layer 16B, the central support layer 14C, the sacrificial layer 16C, and the top support layer 14D may be formed using physical vapor deposition, chemical vapor deposition, atomic layer deposition, evaporation, sputtering, or a combination thereof, but the present disclosure is not limited thereto.

Next, multiple vias H1 are formed in the array area 10A. The vias H1 penetrate the top support layer 14D, the sacrificial layer 16C, the central support layer 14C, the sacrificial layer 16B, the additional support layer 14B, the protective layer 16A, and the bottom support layer 14A, and expose the landing pads 12A. For example, a patterning process may be performed to form the vias H1 based on the positions of the landing pads 12A. The patterning process may include forming a masking layer (not shown) above the top support layer 14D, followed by etching the portions not covered by the masking layer. However, the present disclosure is not limited thereto.

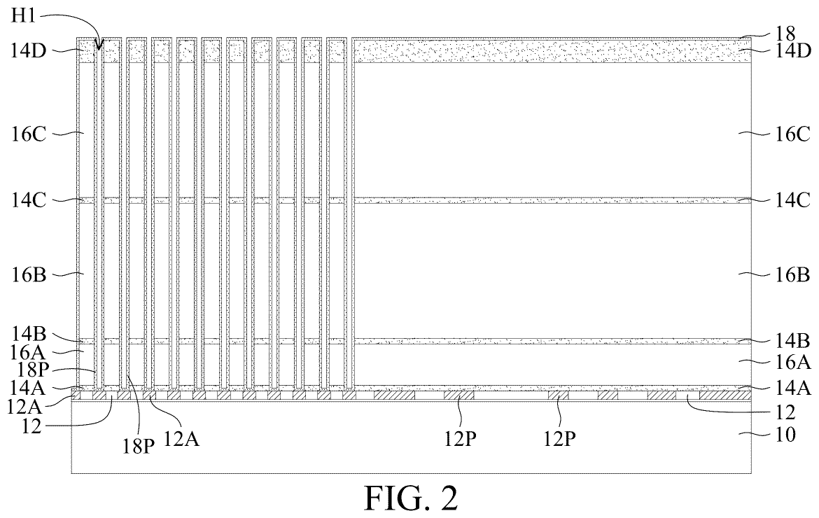

Referring to FIG. 2, a conductive layer 18 is formed on the bottoms and sidewalls of the vias H1 to form multiple conductive pillars 18P. The conductive layer 18 (or conductive pillars 18P) may include a conductive material, such as metal, metal silicide, or a combination thereof. For example, the metal may include gold, nickel, platinum, palladium, iridium, titanium, chromium, tungsten, aluminum, copper, an alloy thereof, or a combination thereof. The conductive layer 18 may be formed using physical vapor deposition, chemical vapor deposition, atomic layer deposition, evaporation, sputtering, any similar process, or a combination thereof, but the present disclosure is not limited thereto.

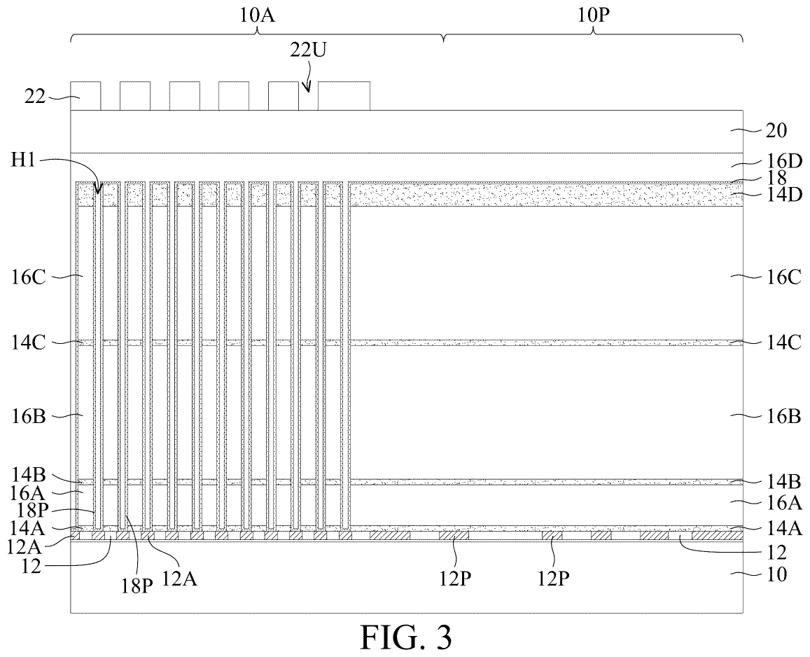

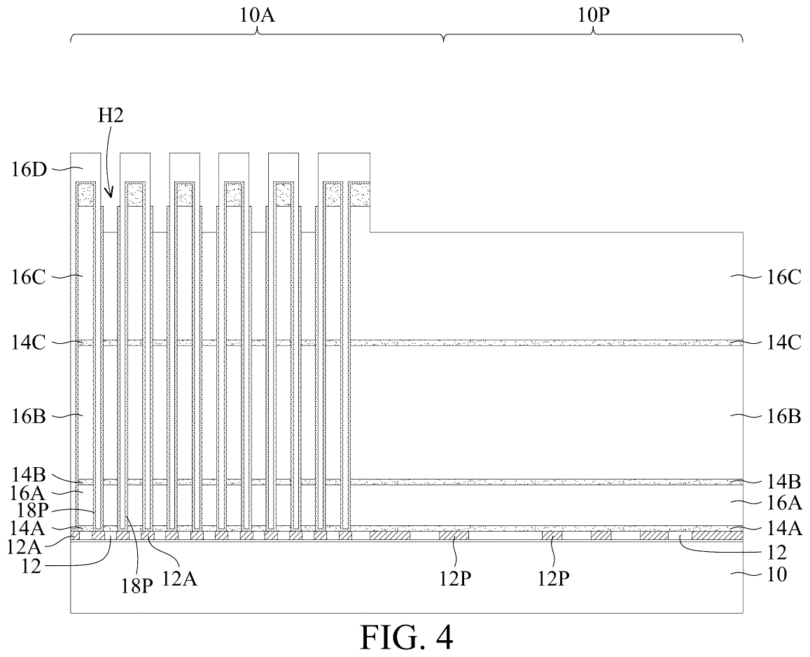

Next, multiple vias H2 that are interleaved with the vias H1 are formed in the array area 10A. In more detail, referring to FIG. 3 and FIG. 4, a sacrificial layer 16D is first formed on the conductive layer 18 (conductive pillars 18P). Then, a photoresist layer 20 and a masking layer 22 are sequentially formed on the sacrificial layer 16D. The photoresist layer 20 may be, for example, a positive photoresist. The masking layer 22 may include a hard mask and may be formed of silicon oxide, silicon nitride, silicon oxynitride, silicon carbide, silicon carbonitride, or a combination thereof. The masking layer 22 may be a single-layer structure or multi-layer structure, and may be formed using a deposition process.

The photoresist layer 20 may be exposed to light (e.g., UV light) through the transparent regions 22U of the masking layer 22. The vias H2 may be formed using a photolithography process. For example, the photolithography process may include photoresist coating (e.g., spin coating), soft baking, mask alignment, exposure, post-exposure baking (PEB), development, cleaning, drying (e.g., hard baking), any other suitable process, or a combination thereof.

Referring to FIG. 4, the masking layer 22 and the photoresist layer 20 are removed. Next, in the array area 10A, a portion of the sacrificial layer 16D, a portion of the conductive layer 18, a portion of the top support layer 14D, and a portion of the sacrificial layer 16C are removed through the vias H2. In the peripheral area 10P, the sacrificial layer 16D, the conductive layer 18, and the top support layer 14D are completely removed, and a portion of the sacrificial layer 16C is removed. In one embodiment, a wet etching process is performed to remove the sacrificial layer 16D, a chemical mechanical polishing (CMP) process is performed to remove a portion of the conductive layer 18, and a dry etching process is performed to remove the top support layer 14D and a portion of the conductive layer 18. However, the present disclosure is not limited thereto.

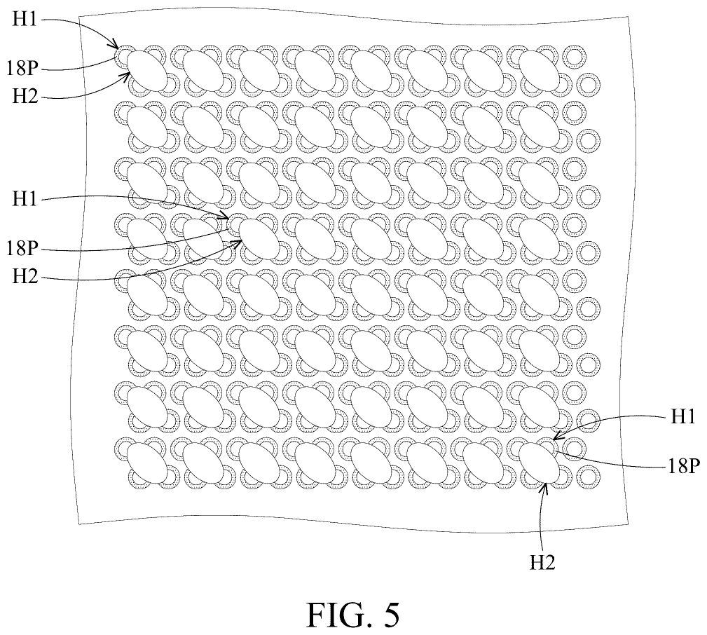

FIG. 5 is a partial top view illustrating the vias H1, the vias H2, and the conductive pillars 18P according to an embodiment of the present disclosure, showing the arrangement (or relative positions) of the vias H1 and the vias H2. It should be noted that the positions of the vias H1 and the vias H2 are not limited to the arrangement shown in FIG. 5. As shown in FIG. 5, in one embodiment, each via H2 overlaps at least a portion of adjacent via H1. For example, in the example shown in FIG. 5, each via H2 may overlap four vias H1, but the present disclosure is not limited thereto.

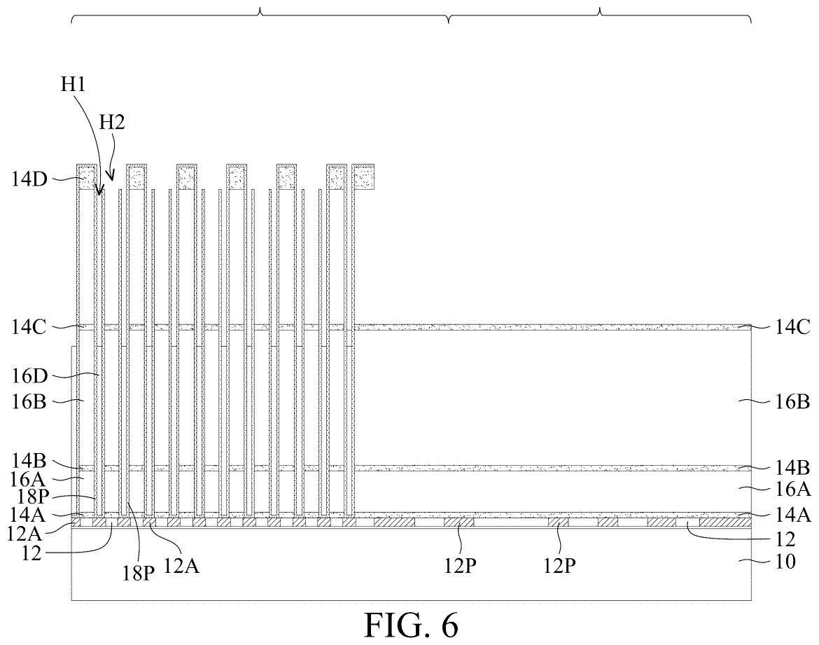

Referring to FIG. 6, a portion of the sacrificial layer 16D are removed, and the sacrificial layer 16C is completely removed. In one embodiment, a wet etching process is performed to remove a portion of the sacrificial layer 16D and the sacrificial layer 16C. The sacrificial layer 16C exhibits high etching selectivity relative to the central support layer 14C. Thus, during the removal of the sacrificial layer 16C, most of the central support layer 14C remains. In other words, the central support layer 14C may serve as an etch stop layer.

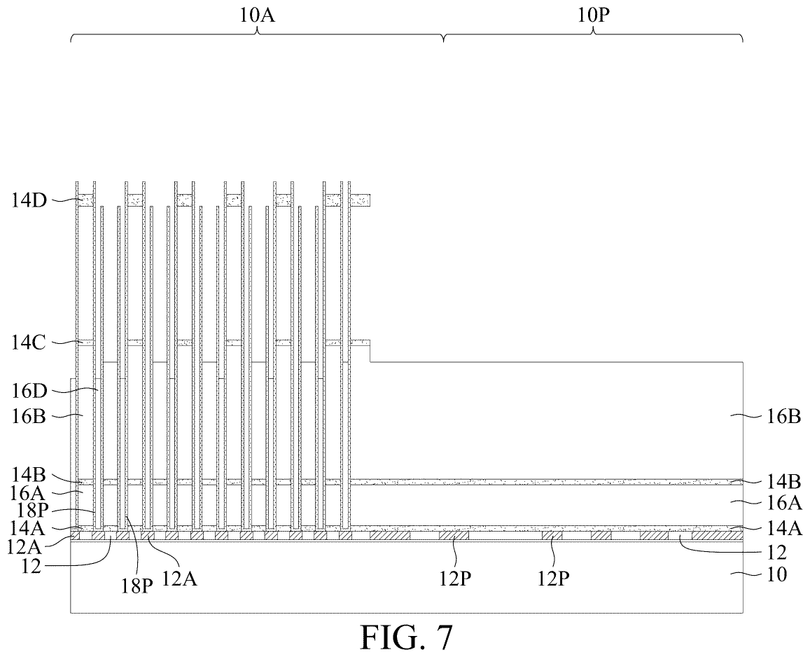

Referring to FIG. 7, in the array area 10A, a portion of the central support layer 14C is removed through the vias H2, while another portion of the central support layer 14C between the conductive pillars 18P is remained. In the peripheral area 10P, the central support layer 14C is completely removed. In other words, in the array area 10A, the portion of the central support layer 14C that corresponds to the vias H2 is removed, while other portions are remained. In one embodiment, a dry etching process is performed to remove the central support layer 14C.

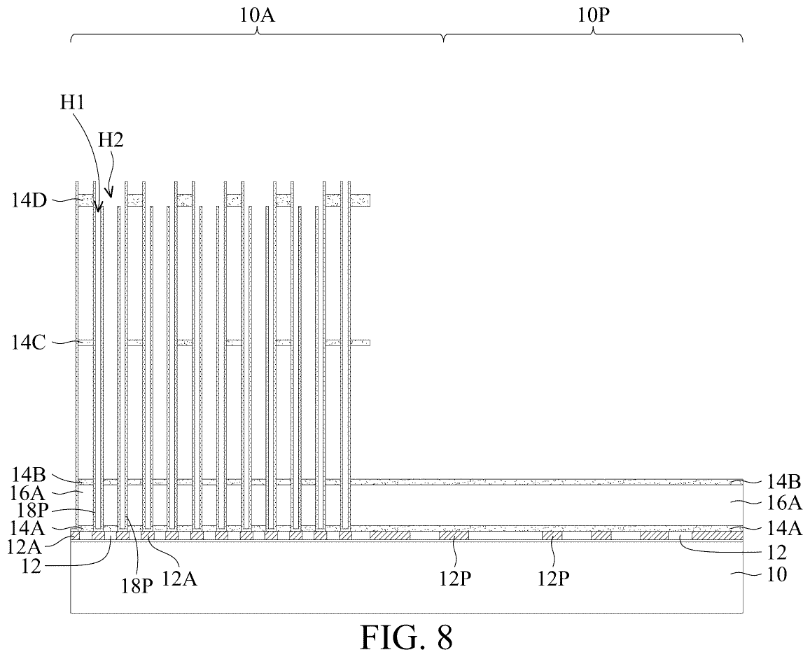

Referring to FIG. 8, the sacrificial layer 16D and the sacrificial layer 16B are completely removed. In one embodiment, a wet etching process is performed to remove the sacrificial layer 16D and the sacrificial layer 16B. The sacrificial layer 16B exhibits high etching selectivity relative to the additional support layer 14B. Therefore, during the removal of the sacrificial layer 16B, most of the additional support layer 14B remains. In other words, the additional support layer 14B may serve as an etch stop layer.

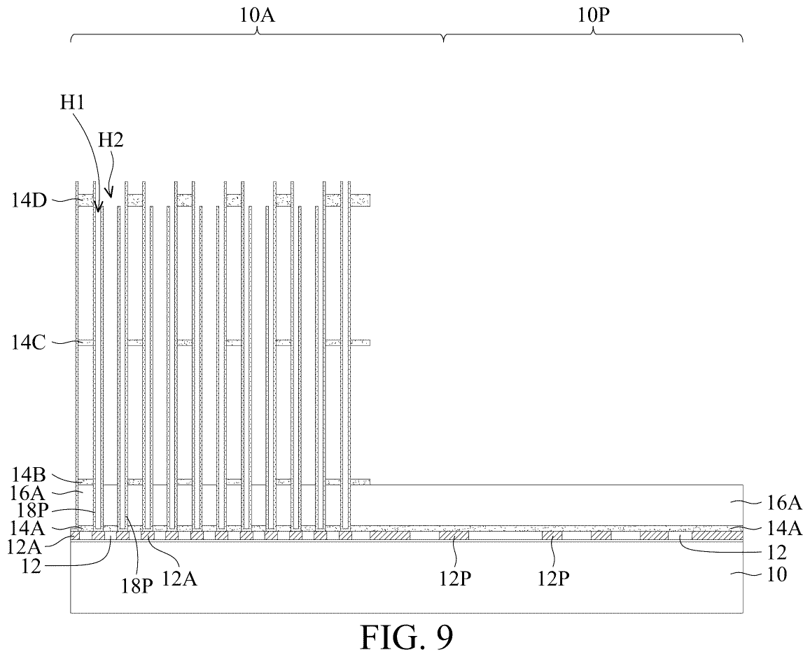

Referring to FIG. 9, in the array area 10A, a portion of the additional support layer 14B is removed through the vias H2, while another portion of the additional support layer 14B between the conductive pillars 18P is remained. In the peripheral area 10P, the additional support layer 14B is completely removed. In other words, in the array area 10A, the portion of the additional support layer 14B that corresponds to the vias H2 is removed, while other portions are remained. In one embodiment, a dry etching process is performed to remove the additional support layer 14B.

Overall, during the stages shown in FIG. 4 and FIG. 6 to FIG. 9, multiple wet etching processes are performed in both the array area 10A and the peripheral area 10P to completely remove the sacrificial layer 16D, the sacrificial layer 16C, and the sacrificial layer 16B. Moreover, in the array area 10A, multiple dry etching processes are performed to remove the portions of the top support layer 14D, the central support layer 14C, and the additional support layer 14B that correspond to the vias H2, while other portions are remained. In the peripheral area 10P, these layers are completely removed.

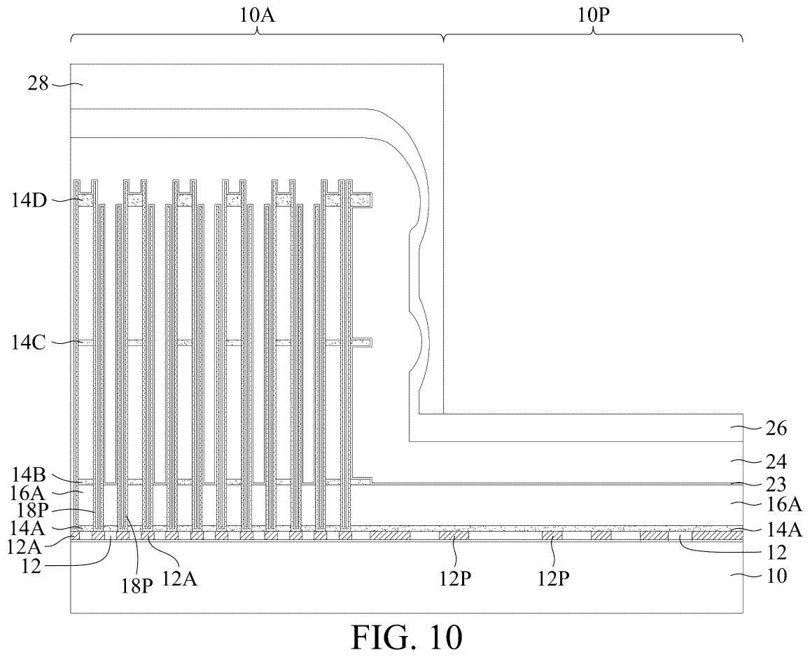

Referring to FIG. 10, in the array area 10A, a high-K dielectric layer 23 and a semiconductor layer 24 are sequentially formed in each conductive pillar 18P and between the conductive pillars 18P. In the peripheral area 10P, the high-K dielectric layer 23 and the semiconductor layer 24 are sequentially formed on the protective layer 16A. The semiconductor layer 24 may include elemental semiconductors (e.g., silicon or germanium), compound semiconductors (e.g., silicon carbide, gallium arsenide, indium arsenide, or indium phosphide), alloy semiconductors (e.g., SiGe, SiGeC, GaAsP, or GaInP), or a combination thereof. The semiconductor layer 24 may be formed using chemical vapor deposition (CVD), atomic layer deposition (ALD), molecular beam epitaxy (MBE), liquid-phase epitaxy, or a combination thereof. However, the present disclosure is not limited thereto.

Next, a metal layer 26 is formed on the semiconductor layer 24. The metal layer 26 includes metals as previously described, which will not be repeated here. Then, a masking layer 28 is formed on the metal layer 26 in the array area 10A.

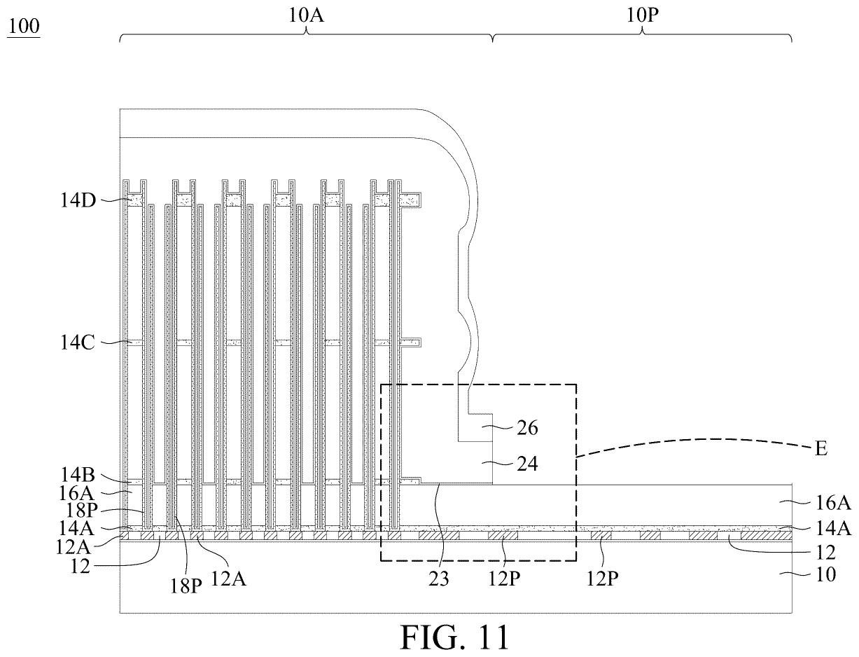

Referring to FIG. 11, portions of the high-K dielectric layer 23, the semiconductor layer 24, and the metal layer 26 in the peripheral area 10P are removed using the masking layer 28 as an etching mask, and the protective layer 16A in the peripheral area 10P is exposed, thereby forming the semiconductor structure 100.

As shown in FIG. 11, the semiconductor structure 100 includes a substrate 10 and multiple landing pads 12A. The substrate 10 has an array area 10A and a peripheral area 10P, and the landing pads 12A are disposed on the substrate 10 and in the array area 10A. The semiconductor structure 100 also includes multiple conductive pillars 18P and a bottom support layer 14A. The conductive pillars 18P are disposed on the landing pads 12A, and the bottom support layer 14A is disposed between the bottoms of the conductive pillars 18P. The semiconductor structure 100 further includes a protective layer 16A and an additional support layer 14B. The protective layer 16A is disposed on the bottom support layer 14A, and the additional support layer 14B is disposed on the protective layer 16A. Moreover, the semiconductor structure 100 includes a central support layer 14C and a top support layer 14D. The central support layer 14C is disposed above the additional support layer 14B, and the top support layer 14D is disposed above the central support layer 14C. The additional support layer 14B, the central support layer 14C, and the top support layer 14D are all between the conductive pillars 18P.

The semiconductor structure 100 also includes multiple metal pads 12P disposed on the substrate 10 and in the peripheral area 10P. Furthermore, the bottom support layer 14A and the protective layer 16A are also disposed on the metal pads 12P. An insulating layer 12 is disposed between the landing pads 12A, between the metal pads 12P, and between the landing pads 12A and the metal pads 12P. The semiconductor structure 100 further includes a semiconductor layer 24 and a metal layer 26. The semiconductor layer 24 is disposed in each conductive pillar 18P and between the conductive pillars 18P, and the metal layer 26 is disposed on the semiconductor layer 24. Moreover, the semiconductor structure 100 includes a high-K dielectric layer 23 disposed between the semiconductor layer 24 and the conductive pillars 18P.

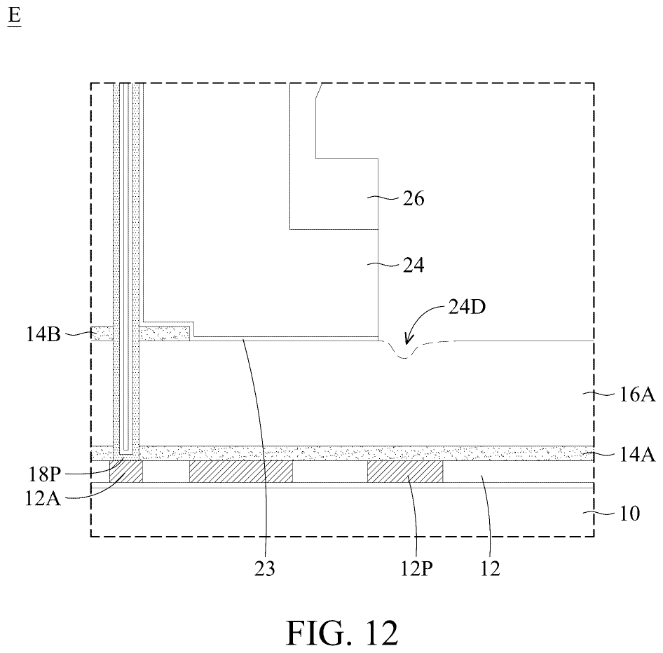

FIG. 12 is a partially enlarged cross-sectional view illustrating region E of the semiconductor structure 100 according to an embodiment of the present disclosure. As shown in FIG. 12, after portions of the semiconductor layer 24 and the metal layer 26 in the peripheral area 10P are removed using the masking layer 28, defects 24D may be formed at the boundaries due to (etching) process factors. Since the semiconductor structure 100 according to the embodiment of the present disclosure includes the protective layer 16A, the defects 24D are formed in the protective layer 16A, preventing damage to the underlying metal pads 12P or the substrate 10. This effectively enhances the yield of the semiconductor structure 100.

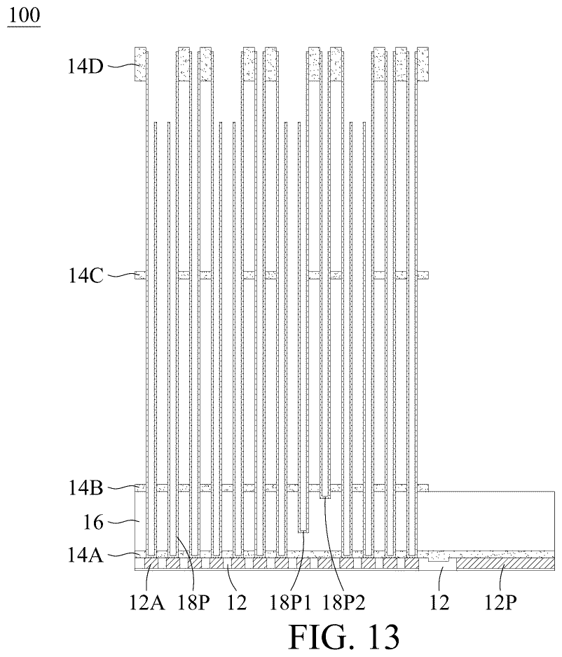

FIG. 13 is a partial cross-sectional view illustrating the semiconductor structure 100 when defects occur according to some other embodiments of the present disclosure. As shown in FIG. 13, when the conductive pillars 18P1 and 18P2 fail to connect with the landing pads 12A, resulting in an open circuit, the semiconductor structure 100, which includes the protective layer 16A and the additional support layer 14B, can still effectively secure the conductive pillars 18P1 and 18P2. This prevents the conductive pillars 18P1 and 18P2 from tilting and connecting with other conductive pillars 18P, which could otherwise cause a short circuit. As a result, the yield of the semiconductor structure 100 is effectively enhanced. Furthermore, the protective layer 16A and the additional support layer 14B also improve the stability of the semiconductor structure 100 during the manufacturing process, thereby reducing the possibility of open circuits.

What is claimed is:

1. A semiconductor structure, comprising:
a substrate having an array area and a peripheral area;
a plurality of landing pads disposed on the substrate and in the array area;
a plurality of conductive pillars disposed on the landing pads;
a bottom support layer disposed between bottoms of the conductive pillars;
a protective layer disposed on the bottom support layer;
an additional support layer disposed on the protective layer;
a central support layer disposed above the additional support layer; and
a top support layer disposed above the central support layer,
wherein the additional support layer, the central support layer, and the top support layer are all between the conductive pillars.

2. The semiconductor structure as claimed in claim 1, further comprising:
a plurality of metal pads disposed on the substrate and in the peripheral area.

3. The semiconductor structure as claimed in claim 2, wherein the bottom support layer and the protective layer are also disposed on the metal pads.

4. The semiconductor structure as claimed in claim 2, further comprising:
an insulating layer disposed between the landing pads and between the metal pads.

5. The semiconductor structure as claimed in claim 1, wherein the protective layer and the additional support layer are made of different materials.

6. The semiconductor structure as claimed in claim 1, wherein the protective layer and the additional support layer exhibit high etching selectivity.

7. The semiconductor structure as claimed in claim 1, wherein the protective layer comprises an oxide.

8. The semiconductor structure as claimed in claim 1, wherein the additional support layer comprises a nitride.

9. The semiconductor structure as claimed in claim 1, wherein the bottom support layer, the central support layer, and the top support layer comprise a nitride.

10. The semiconductor structure as claimed in claim 1, further comprising:
a semiconductor layer disposed within each of the conductive pillars and between the conductive pillars; and
a metal layer disposed on the semiconductor layer.

11. The semiconductor structure as claimed in claim 1, further comprising:
a high-K dielectric layer disposed between the semiconductor layer and the conductive pillars.

12. A method for forming a semiconductor structure, comprising:
providing a substrate, wherein the substrate has an array area and a peripheral area;
forming a plurality of landing pads on the substrate, wherein the landing pads are in the array area;
sequentially forming a bottom support layer, a protective layer, an additional support layer, a first sacrificial layer, a central support layer, a second sacrificial layer, and a top support layer above the substrate;
forming a plurality of first vias in the array area, wherein the first vias penetrate the top support layer, the second sacrificial layer, the central support layer, the first sacrificial layer, the additional support layer, the protective layer, and the bottom support layer, and expose the landing pads;
forming a conductive layer on bottoms and sidewalls of the first vias to form a plurality of conductive pillars;
forming a plurality of second vias interleaved with the first vias in the array area, wherein each of the second vias at least partially overlaps adjacent first vias; and
removing the second sacrificial layer and the first sacrificial layer through the second vias, and removing portions of the top support layer, the central support layer, and the additional support layer that correspond to the second vias, so that the remaining additional support layer, central support layer, and top support layer are all between the conductive pillars.

13. The method for forming a semiconductor structure as claimed in claim 12, further comprising:
forming a plurality of metal pads on the substrate, wherein the metal pads are in the peripheral area.

14. The method for forming a semiconductor structure as claimed in claim 13, wherein the bottom support layer and the protective layer are also formed on the metal pads.

15. The method for forming a semiconductor structure as claimed in claim 12, wherein a wet etching process is performed to remove the second sacrificial layer and the first sacrificial layer.

16. The method for forming a semiconductor structure as claimed in claim 12, wherein a dry etching process is performed to remove portions of the top support layer, the central support layer, and the additional support layer that correspond to the second vias.

17. The method for forming a semiconductor structure as claimed in claim 12, further comprising:
sequentially forming a high-K dielectric layer and a semiconductor layer in each of the conductive pillars and between the conductive pillars.

18. The method for forming a semiconductor structure as claimed in claim 12, further comprising:
forming a metal layer on the semiconductor layer.
